(19) United States
(12) Patent Application Publication
(10) Pub. No.: US 2026/0240029 A1
(43) Pub. Date: Aug. 13, 2026

(54) SEMICONDUCTOR PACKAGE INCLUDING CONDUCTIVE POST STRUCTURE

(71) Applicant: SAMSUNG ELECTRONICS CO., LTD., Suwon-si (KR)

(72) Inventor: Jaesic LEE, Suwon-si (KR)

(73) Assignee: SAMSUNG ELECTRONICS CO., LTD., Suwon-si (KR)

(21) Appl. No.: 19/455,125

(22) Filed: Jan. 21, 2026

(30) Foreign Application Priority Data
Feb. 12, 2025 (KR) 10-2025-0017940

(51) Int. Cl. H10W 72/00

(52) U.S. Cl. CPC H10W 72/823

(57) ABSTRACT

A semiconductor package may include: a lower redistribution layer structure including a lower redistribution pattern; a semiconductor chip on the lower redistribution layer structure; a conductive post structure on the lower redistribution layer structure; a sealing member contacting a sidewall of the conductive post structure and covering the semiconductor chip ; and an upper redistribution layer structure on upper surfaces of the sealing member and the conductive post structures. The conductive post structure includes a first conductive post extending from an upper surface of the lower redistribution layer structure in a vertical direction; and a second conductive post on an upper surface of the first conductive post. A sidewall of the second conductive post may have a slope such that a width of the second conductive post gradually decreases from a top to a bottom thereof.

### CROSS-REFERENCE TO RELATED APPLICATION

This application claims priority under 35 USC § 119 to Korean Patent Application No. 10-2025-0017940, filed on Feb. 12, 2025, in the Korean Intellectual Property Office, the disclosure of which is incorporated herein in its entirety by reference.

### BACKGROUND

Various example embodiments relate to a semiconductor package including a Fan-Out Wafer-Level Package (FOWPLP).

In the Fan-Out Wafer-Level Package, conductive posts having a pillar shape may be used to electrically connect an upper chip and a lower chip. However, when an adhesion between the conductive post and a sealing member is insufficient and cracks occur in the conductive posts, delamination may occur at an interface between an upper portion of the conductive post and the sealing member. Therefore, a reliability of the semiconductor package may be decreased.

### SUMMARY

The disclosure provides a semiconductor package having improved device characteristics and a method of manufacture the same.

According to one or more embodiments, there is provided a semiconductor package which may include: a lower redistribution layer structure including a lower redistribution pattern; a semiconductor chip on the lower redistribution layer structure, the semiconductor chip electrically connected to the lower redistribution pattern; a conductive post structure on the lower redistribution layer structure, the conductive post structure electrically connected to the lower redistribution layer structure; a sealing member on the lower redistribution layer structure, the sealing member contacting a sidewall of the conductive post structures and covering the semiconductor chip; and an upper redistribution layer structure on upper surfaces of the sealing member and the conductive post structure. The conductive post structure may include: a first conductive post extending from an upper surface of the lower redistribution layer structure in a vertical direction, a sidewall of the first conductive post having a vertical slope; and a second conductive post on an upper surface of the first conductive post. A width of the second conductive post may decrease from a top to a bottom thereof. The second conductive post may have a portion positioned lower than an uppermost surface of the first conductive post.

According to one or more example embodiments, there is provided a semiconductor package which may include: a lower redistribution layer structure including a lower insulation layer, a lower redistribution pattern and a bonding pad; a semiconductor chip on the lower redistribution layer structure, the semiconductor chip electrically connected to the lower redistribution patterns; a sealing member on the lower redistribution layer structure and the first semiconductor chip; a conductive post structure passing through the sealing member and being spaced apart from the semiconductor chip; and an upper redistribution layer structure on the conductive post structure, the redistribution layer structure including an upper insulation layer and an upper redistribution pattern electrically connected to the conductive post structure. The conductive post structure may contact a portion of the bonding pad. A surface downward from an uppermost edge of the conductive post structure may include an uneven portion having unevenness.

According to one or more example embodiments, there is provided a semiconductor package which may include: a lower redistribution layer structure including a lower redistribution pattern; an upper redistribution layer structure being spaced apart from and facing the lower redistribution layer structure, and the upper redistribution layer structure including an upper redistribution pattern; and a conductive post structure disposed between the lower redistribution layer structure and the upper redistribution layer structure to connect the lower redistribution layer structure and the upper redistribution layer structure. The conductive post structure may include: a first conductive post extending from an upper surface of the lower redistribution layer structure in a vertical direction, and an upper width and a lower width of the first conductive post being equal; and a second conductive post on the first conductive post on an upper surface of the first conductive post. A sidewall of the second conductive post may have a slope such that a width of the second conductive post decreases from a top to a bottom thereof.

In a semiconductor package according to one or more embodiments, cracks of the upper portion of the conductive post structure may be avoided or reduced. Further, delamination may be reduced at an interface between the upper portion of the conductive post structure and the sealing member. Accordingly, defects of the semiconductor package may be reduced, and a reliability of the semiconductor package may be enhanced.

However, the effects of the disclosure are not limited to the above-mentioned effects, and may be variously expanded within a scope that does not depart from a spirit and a range of the disclosure.

### BRIEF DESCRIPTION OF DRAWINGS

Various example embodiments will be more clearly understood from the following detailed description taken in conjunction with the accompanying drawings. FIGS. 1 to 23 represent various non-limiting, example embodiments as described herein.

FIG. 1 is a cross-sectional view illustrating a semiconductor package according to one or more example embodiments;

FIG. 2 is a plan view illustrating a semiconductor package according to one or more example embodiments;

FIG. 3 is an enlarged cross-sectional view of a conductive post structure of a semiconductor package according to one or more example embodiments;

FIG. 4 is an enlarged cross-sectional view of a conductive post structure of a semiconductor package according to one or more example embodiments;

FIGS. 5 to 18 are cross-sectional views illustrating a method for manufacturing a semiconductor package according to one or more example embodiments;

FIG. 19 is a cross-sectional view illustrating a semiconductor package according to one or more example embodiments;

FIG. 20 is an enlarged cross-sectional view of a conductive post structure of a semiconductor package according to one or more example embodiments;

FIG. 21 is a cross-sectional view illustrating a semiconductor package according to one or more example embodiments;

FIG. 22 is an enlarged cross-sectional view of a conductive post structure of a semiconductor package according to one or more example embodiments; and

FIG. 23 is a cross-sectional view illustrating a semiconductor package according to one or more example embodiments.

### DETAILED DESCRIPTION

Hereinafter, various embodiments will be described in detail with reference to the accompanying drawings. The embodiments described herein are non-limiting example embodiments, and thus, the disclosure is not limited thereto and may be realized in various other forms. Each of the embodiments provided herein is not excluded from being associated with one or more features of another example or another embodiment also provided herein or not provided herein but consistent with the disclosure. For example, even if matters described in a specific example or embodiment are not described in a different example or embodiment, the matters may be understood as being related to or combinable with the different example or embodiment, unless otherwise mentioned in descriptions thereof.

As used herein, when an element or layer is referred to as "covering", "overlapping", "surrounding", "exposing", and the like, another element or layer, the element or layer may cover, overlap, surround, and/or expose at least a portion of the other element or layer, where the portion may include a fraction of the other element or may include an entirety of the other element. Further, when two or more elements are described as being "electrically connected," these elements may be in a state of electrically connected through a conductive medium such as wire or being configured to be electrically connected through the conductive medium when power is supplied.

It will be understood that when an element or layer is referred to as being "over," "above," "on," "below," "under," "beneath," "connected to" or "coupled to" another element or layer, it can be directly over, above, on, below, under, beneath, connected or coupled to the other element or layer or intervening elements or layers may be present. In contrast, when an element is referred to as being "directly over," "directly above," "directly on," "directly below," "directly under," "directly beneath," "directly connected to" or "directly coupled to" another element or layer, there are no intervening elements or layers present.

Spatially relative terms, such as "over," "above," "on," "upper," "below," "under," "beneath," "lower," "left," "right," and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as "below" or "beneath" other elements or features would then be oriented "above" the other elements or features. Thus, the term "below" can encompass both an orientation of above and below. The device may be otherwise oriented (rotated 90 degrees or at other orientations) and the spatially relative descriptors used herein interpreted accordingly.

It is to be understood that a term, "about" or "substantially" as used herein with regard to thicknesses, widths, percentages, ranges, etc., are meant to denote being close or approximate to, but not exactly. For example, the term "about" or "substantially" as used herein implies that a small margin of error may be present, such as 5 % or less than the stated amount. Further, when two or more elements (or components, or layers) are described as being "electrically connected," these elements may be in a state of electrically connected through a conductive medium such as wire or being configured to be electrically connected through the conductive medium when power is supplied.

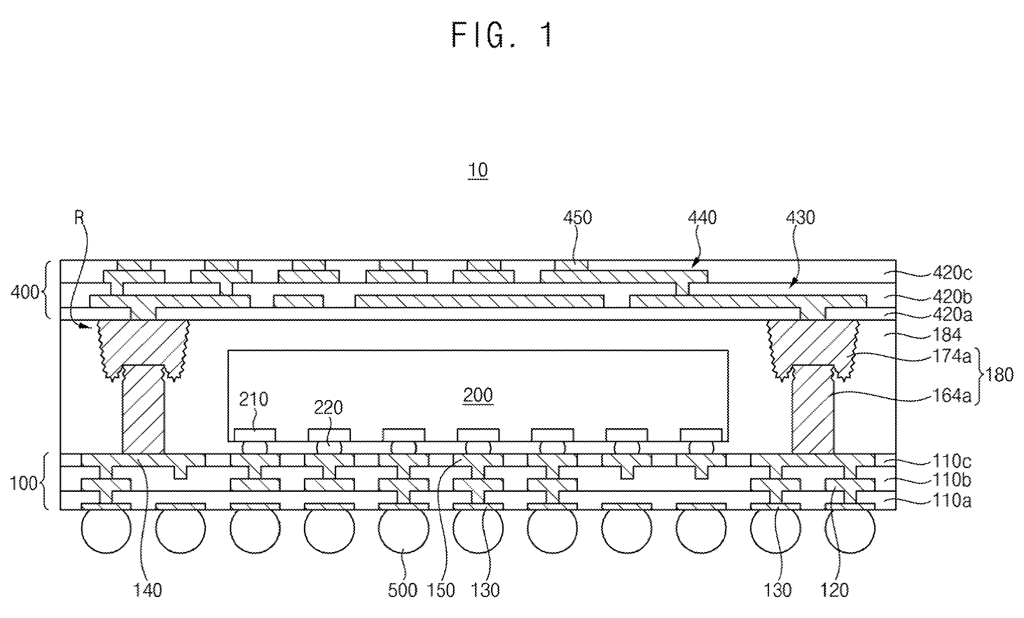

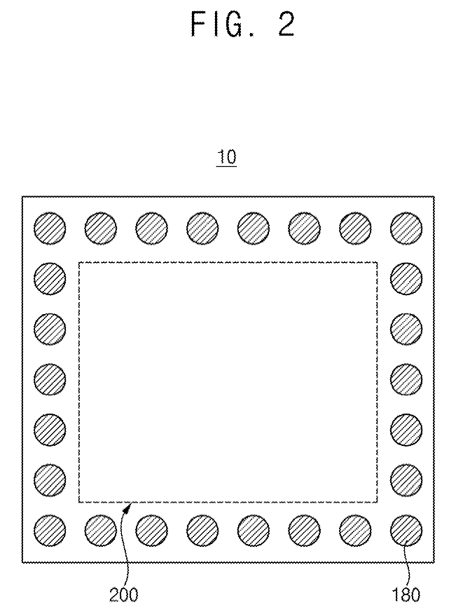

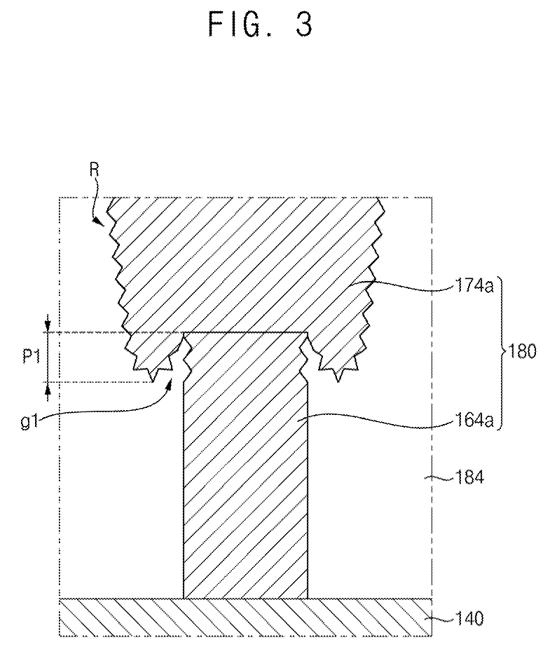

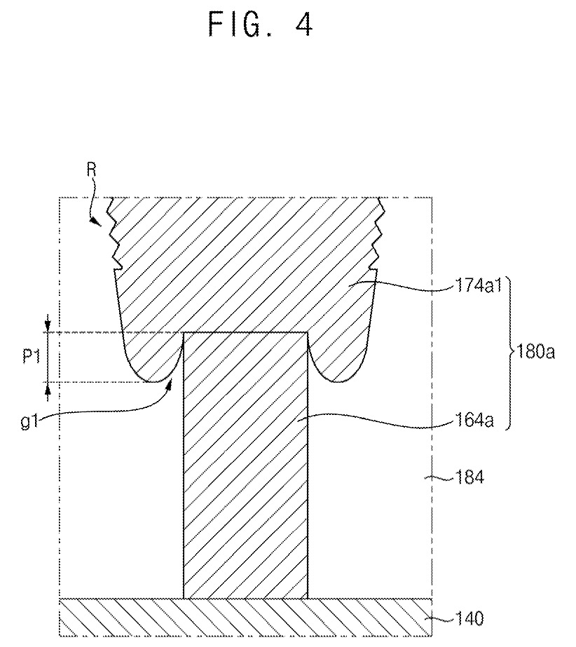

FIG. 1 is a cross-sectional view illustrating a semiconductor package according to one or more example embodiments. FIG. 2 is a plan view illustrating a semiconductor package according to one or more example embodiments. FIG. 3 is an enlarged cross- sectional view of a conductive post structure of a semiconductor package according to one or more example embodiments. FIG. 4 is an enlarged cross-sectional view of a conductive post structure of a semiconductor package according to one or more example embodiments.

Referring to FIGS. 1 to 3, a semiconductor package 10 may include a lower redistribution layer structure 100, a first semiconductor chip 200 disposed on the lower redistribution layer structure 100, a first sealing member 184 covering the first semiconductor chip 200 on an upper surface, also referred to as a top surface, of the lower redistribution layer structure 100, conductive post structures 180 passing through the first sealing member 184, and an upper redistribution layer structure 400 disposed on the first sealing member 184 and the conductive post structures 180. Further, an external connection member 500 may be disposed on a bottom or bottom surface of the lower redistribution layer structure 100.

In one or more example embodiments, the semiconductor package 10 may be a fan-out package in which the lower redistribution layer structure 100 extends to the first sealing member 184 covering an outer sidewall of the first semiconductor chip 200.

In one or more example embodiments, the semiconductor package 10 may be a System In Package (SIP). For example, one or more first semiconductor chips 200 may be stacked on the lower redistribution layer structure 100. The first semiconductor chip 200 may include a logic chip including logic circuits. The logic chip may be a controller that controls one or more other devices, for example, memory chips. In one or more example embodiments, the first semiconductor chip 200 may be a processor chip such as an application-specific integrated circuit (ASIC) serving as a host, such as a central processing unit (CPU), a graphic processing unit (GPU), or a system-on-chip (SOC), or an application processor (AP).

The lower redistribution layer structure 100 may include lower insulation layers 110a,110b and 110c, lower redistribution patterns 120, a lower pad 130, a first bonding pad 140, and a second bonding pad 150. The first semiconductor chip 200 electrically connected to the lower redistribution patterns 120 may be disposed on the lower redistribution layer structure 100. The lower redistribution layer structure 100 may function as a front redistribution layer arranged to face a front surface of the first semiconductor chip 200. Therefore, the lower redistribution layer structure 100 may be a front redistribution layer (FRDL) of the fan-out package.

In one or more example embodiments, the lower redistribution layer structure 100 may include first, second and third lower insulation layers 110a, 110b and 110c. The first bonding pad 140 and the second bonding pad 150 may be arranged on the third lower insulation layer 110c, which is an uppermost lower insulation layer. The first bonding pads 140 may be pads that are in contact with the conductive post structures 180, and the second bonding pads 150 may be pads that are electrically connected to the first semiconductor chip 200. In addition, the lower redistribution patterns 120 may be arranged in or within the lower insulation layer (e.g., the second lower insulation layer 110b) between the uppermost lower insulation layer and a lowermost lower insulation layer. The lower redistribution patterns 120 may be constructed by stacking multiple layers.

The first, second and third lower insulation layers ll0a, 110b and 110c may include, e.g., a polymer, a dielectric layer, etc. For example, the first, second and third lower insulation layers 110a, 110b and 110c may include a photosensitive insulation layer such as a photo imageable dielectric (PID).

The lower redistribution patterns 120 may include, e.g., copper (Cu), aluminum (Al), tin (Sn), nickel (Ni), gold (Au), silver (Ag), platinum (Pt), or an alloy thereof. In one or more example embodiments, each of the lower redistribution patterns 120 may include a via contact and a wiring line.

Each of the first bonding pad 140 and the second bonding pad 150 may include, e. g., copper (Cu), aluminum (Al), tin (Sn), nickel (Ni), gold (Au), silver (Ag), platinum (Pt), or an alloy thereof. The upper surfaces of the first bonding pad 140 and the second bonding pad 150 may be exposed without being covered by the third lower insulation layer 110c.

The number and an arrangement, etc. of the lower insulation layers 110a, 110b and 110c and the lower redistribution patterns 120 within the lower redistribution layer structure 100 are described as examples. Therefore, it will be understood that the present disclosure is not limited thereto.

The external connection members 500 may be disposed on the lower pads 130 of the lower redistribution layer structure 100, and may be electrically connected to the lower redistribution patterns 120, respectively. The external connection members 500 may include, e.g., solder balls, conductive bumps, etc.

In one or more example embodiments, a first surface, i.e., an active surface of the first semiconductor chip 200 may have a plurality of chip pads 210. The first semiconductor chip 200 may be mounted on the lower redistribution layer structure 100 such that the first surface on which the chip pads 210 are formed faces the lower redistribution layer structure 100.

The first semiconductor chip 200 may be mounted on the lower redistribution layer structure 100 with conductive bumps 220 interposed therebetween. Each of the conductive bumps 220 may be arranged between the second bonding pad 150 of the lower redistribution layer structure 100 and the chip pad 210 of the first semiconductor chip 200. The first semiconductor chip 200 and the lower redistribution layer structure 100 may be electrically connected to the conductive bumps 220. For example, a conductive bump 220 may include a pillar bump on a chip pad 210 of the first semiconductor chip 200 and a solder bump on the pillar bump.

In one or more example embodiments, the first semiconductor chip 200 may be placed on a center region of the upper surface of the lower redistribution structure 100. However, the placement of the first semiconductor chip 200 is not limited thereto. The placement of the first semiconductor chip 200 may vary depending on an arrangement of the conductive post structures 180 described below.

Although only a few chip pads 210 are illustrated in the drawings, a structure and an arrangement of the chip pads are not limited thereto. Further, in FIG. 1, although only one first semiconductor chip 200 is placed on the lower redistribution structure 100, the disclosure is not limited thereto. That is, a plurality of first semiconductor chips 200 may be arranged or stacked on the lower redistribution layer structure 100.

Each of the conductive post structures 180 may extend upward from the upper surface of the lower redistribution layer structure 100 while in contact with the first bonding pad 140. The conductive post structures 180 may be spaced apart from the first semiconductor chip 200. The conductive post structures 180 may be electrically connected to the lower redistribution layer structure 100.

An upper surface of a conductive post structure 180 may be coplanar with or higher than an upper surface of the first semiconductor chip 200. A height of the conductive post structure 180 may be greater than a height of the first semiconductor chip 200. The heights of the conductive post structures 180 may vary depending on the height of the first semiconductor chip 200 mounted on the semiconductor package 10.

The conductive post structure 180 may include a first conductive post 164a and a second conductive post 174a on the first conductive post 164a. The first and second conductive posts 164a and 174a may include the same material, and may have a single body. The first and second conductive posts 164a and 174a may include metal. The first and second conductive posts 164a and 174a may include, e.g., copper.

The first conductive post 164a may contact an upper surface of the first bonding pad 140. The first conductive post 164a may be electrically connected to the lower redistribution patterns 120 included in the lower redistribution layer structure 100. The first conductive post 164a may be positioned in a fan-out region corresponding to an outer area of the first semiconductor chip 200 (or die).

The first conductive post 164a may extend from the upper surface of the first bonding pad 140 in a vertical direction. A sidewall of the first conductive post 164a may have a substantially vertical slope. For example, the sidewall of the first conductive post 164A may be substantially vertical with respect to an upper or top surface of the first bonding pad 140 therebelow which may be horizontally coplanar with an upper or top surface of the third lower insulation layer 110c. Accordingly, a width of the first conductive post 164a may be substantially the same in each vertical level in a horizontal direction. In example embodiments, a lower width of the first conductive post 164a and an upper width of the first conductive post 164a may be substantially the same. Herein, the lower width and the upper width may refer to a width of a lower portion of a corresponding structure and a width of an upper portion of the corresponding structure.

In one or more example embodiments, the first conductive post 164a may have a height greater than or equal to 50% and less than or equal to 80% of the height of the conductive post structure 180 in a vertical direction. When the height of the first conductive post 164a is less than 50% of the height of the conductive post structure 180, the height of the second conductive post 174a increases relatively. Therefore, processes for forming the second conductive post 174a may not easy. When the height of the first conductive post 164a is greater than 80% of the height of the conductive post structure 180, the height of the second conductive post 174a decreases relatively. Therefore, effects of reducing of cracks of the conductive post structure 180 and delamination at the upper portion of the conductive post structure 180 may not be significant.

The second conductive post 174a may have a sidewall slope such that a width of the second conductive post 174a may gradually decrease from a top to a bottom thereof. In one or more example embodiments, in a cross-sectional view, the second conductive post 174a may have an inverted trapezoidal shape. An upper width of the second conductive post 174a may be greater than a lower width of the second conductive post 174a.

The second conductive post 174a may disposed on the first conductive post 164a to cover an upper surface of the first conductive post 164a. The lower width of the second conductive post 174a may be greater than the width of the first conductive post 164a. Therefore, an uppermost portion of the second conductive post 174a may have a maximum width in the conductive post structure 180. An upper portion of the conductive post structure 180 may have a maximum horizontal area. An uppermost horizontal area of the conductive post structure 180 may be greater than a lowermost horizontal area of the conductive post structure 180.

A lowermost portion of the second conductive post 174a may be lower than an uppermost surface, also referred to as a topmost surface, of the first conductive post 164a. A portion of the second conductive post 174a that is positioned lower than the uppermost surface of the first conductive post 164a may be referred to as a first portion P1 as shown in FIG. 3. In one or more example embodiments, in a cross-sectional view, the first portion P1 of the second conductive post 174a may have a downwardly rounded shape. In one or more example embodiments, the first portion P1 of the second conductive post 174a may surround an upper sidewall, also referred to as an upper side surface, of the first conductive post 164a while being spaced apart from at least a portion of the upper sidewall of the first conductive post 164a. Accordingly, in a portion adjacent to an interface between the second conductive post 174a and the first conductive post 164a, the first portion P1 of the second conductive post 174a and the upper sidewall of the first conductive post 164a may face each other. A gap gl may be formed between the first portion P1 of the second conductive post 174a and the upper sidewall of the first conductive post 164a.

A surface of the conductive post structure 180 extending downward from the top to a predetermined height may have a relatively high surface roughness, and may have an unevenness (or, surface topography) R. Therefore, at least a portion of a surface of a sidewall, also referred to as a side surface, of the second conductive post 174a may have a relatively high surface roughness, and may have the unevenness R. In one or more example embodiments, a lowermost end, also referred to as a bottom end, of a portion having the unevenness R (i.e., an uneven portion) of the conductive post structure 180 may be positioned higher than a middle height of the conductive post structure 180.

In one or more example embodiments, as in the conductive post structure 180 shown in FIG. 3, an entire sidewall of the second conductive post 174a and the upper sidewall of the first conductive post 164a facing the first portion P1 of the second conductive post 174a may have the unevenness R. A lower sidewall, also referred to as a lower side surface, of the first conductive post 164a may not have the unevenness R.

In one or more example embodiments, as in the conductive post structure 180a shown in FIG. 4, only an upper sidewall, also referred to as an upper side surface, of the second conductive post 174a1 may have the unevenness R. A sidewall, also referred to as a side surface, of the first conductive post 164a may not have the unevenness R.

The unevenness R of the upper sidewall of the conductive post structure 180 may be provided to improve adhesive properties between the first sealing member 184 and the upper sidewall of the conductive post structure 180. A surface of the uneven portion of the upper sidewall of the conductive post structure 180 may have a first arithmetic mean roughness (Ra). In one or more example embodiments, the first arithmetic mean roughness may be in the range of 10 nm to 2000 nm. When the first arithmetic mean roughness is lower than 10nm, an effect of reducing delamination between the first sealing member 184 and the upper sidewall of the conductive post structure 180 may decrease. When the first arithmetic mean roughness is higher than 2000nm, a surface irregularity may increase, and thus uniformity of electrical characteristics of the semiconductor package 10 may decrease. Thus, the surface of the uneven portion of the second conductive posts 174a may have the first arithmetic mean roughness in the range of 10 nm to 2000 nm, for example.

The first sealing member 184 may be disposed on the upper surface of the lower redistribution layer structure 100 to cover the first semiconductor chip 200. The first sealing member 184 may contact the sidewall of the conductive post structure 180. The first sealing member 184 may be or include an encapsulant, e.g., an epoxy mold compound (EMC).

In one or more example embodiments, as shown in FIG. 1, the first sealing member 184 may be formed on a lower surface, sidewalls, and an upper surface of the first semiconductor chip 200. In this case, the upper surface of the first semiconductor chip 200 may be covered by the first sealing member 184.

In one or more example embodiments, the first sealing member 184 may cover the lower surface and sidewalls of the first semiconductor chip 200. In this case, the first sealing member 184 may expose at least a portion of the upper surface of the first semiconductor chip 200. Further, the upper surface of a conductive post structure 180 may be positioned at the same height as an uppermost surface of the first semiconductor chip 200. The upper surface of the conductive post structure 180 may be coplanar with the uppermost surface of the first semiconductor chip 200.

An upper surface of the conductive post structure 180 may not be covered by the first sealing member 184. The upper surface of the conductive post structure 180 and an upper surface of the first sealing member 184 may be substantially coplanar with each other. However, the first sealing member 184 may cover or may be formed on an entire sidewall of the conductive post structure 180.

The first sealing member 184 may fill the gap g1 adjacent to the interface between the first and second conductive posts 164a and 174a. In addition, the first sealing member 184 may surround a lower portion of the second conductive post 174a. The first portion P1 of the second conductive post 174a may be embedded in the first sealing member 184, so that the lower portion of the second conductive post 174a may be strongly supported by the first sealing member 184.

Furthermore, a width of the second conductive post 174a may gradually decrease from the top to the bottom thereof. Therefore, an amount of the first sealing member 184 on the lower sidewall of the second conductive post 174a may be greater than an amount of the first sealing member 184 on the upper sidewall of the second conductive post 174a. Therefore, the lower portion of the second conductive post 174a may be strongly supported by the first sealing member 184.

Accordingly, the conductive post structure 180 may have enhanced endurance with respect to a pressure and a mechanical stress applied to the upper portion of the conductive post structure 180. For example, in processes for forming the first sealing member 184 by grinding a sealant so that the upper surface of the conductive post structure 180 is exposed, the pressure and the mechanical stress may be strongly applied to the upper portion of the conductive post structures 180. However, since the lower portion of the second conductive post 174a of the conductive post structure 180 is strongly supported by the first sealing member 184, cracks of the upper portion of the conductive post structure 180 may decrease during the grinding process. Therefore, delamination caused by cracks of the upper portion of the conductive post structure 180 may decrease.

The conductive post structure 180 may pass through the first sealing member 184. The entire sidewall of the conductive post structure 180 may contact the first sealing member 184. For example, the sidewall of the first conductive post 164a and the sidewall of the second conductive post 174a may contact the first sealing member 184.

In general, an adhesion property between the upper portion of the conductive post structure 180 and the first sealing member 184 may be worse than an adhesion property between the lower portion of the conductive post structure 180 and the first sealing member 184, so that delamination may occur more at the upper portion of the conductive post structure 180. However, as described above, since at least a portion of the sidewall of the second conductive post 174a corresponding to the upper portion of the conductive post structure 180 has the unevenness R so as to have the first arithmetic mean roughness, the adhesion property between the first sealing member 184 and the sidewall of the second conductive post 174a may be improved compared to when the sidewall of the conductive post structure has no unevenness. Accordingly, delamination between the sidewall of the second conductive post 174a and the first sealing member 184 may be avoided or reduced. On the other hand, the sidewall of the first conductive post 164a corresponding to the lower portion of the conductive post structure 180 may hardly delaminate from the first sealing member 184 even if the sidewall of the first conductive post 164a has no unevenness. As only the upper sidewall of the conductive post structure 180 has the unevenness R having the first arithmetic mean roughness, delamination (i.e., feeling or lifting) between the upper sidewall of the conductive post structure 180 and the first sealing member 184 may be avoided or reduced.

In one or more example embodiments, as shown in FIG. 2, the conductive post structures 180 may be arranged to surround the first semiconductor chip 200, and the conductive post structures 180 may be spaced apart from each other.

The conductive post structure 180 may pass through the first sealing member 184, and may serve as an electrical connection path with the first semiconductor chip 200. The conductive post structure 180 may be a through mold via (TMV) passing through the first sealing member 184. The conductive post structures 180 may be arranged in the fan-out region corresponding to the outer area of the first semiconductor chip 200, and may electrically connect the lower redistribution patterns 120 and upper redistribution patterns 430 and 440.

The upper redistribution layer structure 400 may cover the upper surfaces of the first sealing member 184 and the conductive post structures 180. The upper redistribution layer structure 400 may include upper insulation layers 420a, 420b and 420c, upper redistribution patterns 430 and 440, and a third bonding pad 450. The upper redistribution layer structure 400 may be disposed on the first sealing member 184, and may serve as a backside redistribution pattern. Therefore, the upper redistribution layer structure 400 may be a backside redistribution layer (BRDL) in the fan-out package. The upper redistribution layer structure 400 may be electrically connected to the lower redistribution layer structure 100 via the conductive post structures 180.

In one or more example embodiments, the upper redistribution layer structure 400 may include first to third upper insulation layers 420a, 420b and 420c and first and second upper redistribution patterns 430 and 440 within the first to third upper insulation layers 420a, 420b and 420c. The third bonding pad 450 may be disposed on the third upper insulation layer 420c corresponding to the uppermost upper insulation layer.

The first to third upper insulation layers 420a, 420b and 420c may include, e.g., a polymer, a dielectric layer, or the like. For example, the first to third upper insulation layers 420a, 420b and 420c may include a photosensitive insulation layer, such as a photo- imageable dielectric (PID).

The upper redistribution patterns 430 and 440 may include, e.g., copper (Cu), aluminum (Al), tin (Sn), nickel (Ni), gold (Au), silver (Ag), platinum (Pt), or alloys thereof.

In one or more example embodiments, the upper redistribution patterns 430 and 440 may include via contacts and wiring lines.

The first upper insulation layer 420a may contact the upper surface of the second conductive post 174a and the upper surface of the first sealing member 184. The first upper redistribution pattern 430 may include a first via contact passing through the first upper insulation layer 420a and contacting at least a portion of the upper surface of the conductive post structure 180, and a first wiring line disposed on the first upper insulation layer 420a and the first via contact.

The third bonding pad 450 may be disposed within the third upper insulation layer 420c corresponding to an uppermost portion of the upper redistribution layer structure 400.

The third bonding pad 450 may serve as a pad for mounting of an upper package. The third bonding pad 450 may include a metal. In one or more example embodiments, the third bonding pad 450 may include copper (Cu), aluminum (Al), tin (Sn), nickel (Ni), gold (Au), silver (Ag), platinum (Pt), or an alloy thereof. For example, the third bonding pad 450 may include copper, and a surface of the copper may be covered with gold, silver, or nickel by surface-treatment.

As described above, the second conductive post 174a corresponding to the upper portion of the conductive post structure 180 may have increased support ability due to the first sealing member 184, so that the endurance with respect to pressure and stress applied to the upper portion of the conductive post structure 180 may be enhanced. Therefore, occurrence of crack in the upper portion of the conductive post structure 180 may be decreased, and delamination caused by the crack may be decreased.

Since adhesion property between the second conductive post 174a corresponding to the upper portion of the conductive post structure 180 and the first sealing member 184 increases, delamination between the sidewall of the conductive post structure 180 and the first sealing member 184 may decrease. Therefore, the semiconductor package 10 may have high reliability.

Hereinafter, a method for manufacturing the semiconductor package of FIG. 1 may be described.

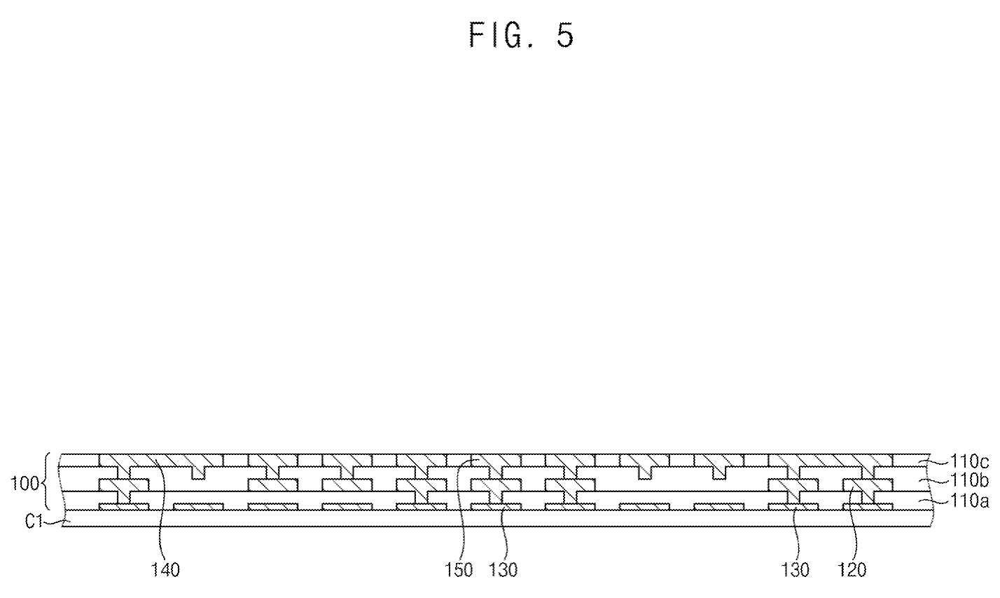

FIGS. 5 to 18 are cross-sectional views illustrating a method for manufacturing a semiconductor package according to one or more example embodiments.

Referring to FIG. 5, a lower redistribution layer structure 100 may be formed on a carrier substrate C1. The lower redistribution layer structure 100 may include lower insulation layers 110a, 110b and 110c, lower redistribution patterns 120, a lower pad 130, a first bonding pad 140, and a second bonding pad 150.

The carrier substrate C1 may be a base substrate for placing a plurality of semiconductor chips on the lower redistribution layer structure 100 and forming a sealing member on the semiconductor chips and the lower redistribution layer structure 100. In one or more example embodiments, the carrier substrate C1 may have a shape corresponding to a wafer on which semiconductor processes are performed. In one or more example embodiments, the carrier substrate C1 may include a silicon substrate, a glass substrate, a non-metallic or metallic plate, etc.

The carrier substrate C1 may include a package region where the semiconductor chips are mounted and a cut region surrounding the package region. In subsequent processes, the lower redistribution layer structure 100 and the first sealing member 184 formed on the carrier substrate C1 may be cut along the cut region to be individualized.

First, a release film may be formed on the carrier substrate C1, and lower pads 130 may be formed on the release film. A first lower insulation layer 110a may be formed on the release film to cover the lower pads 130. Subsequently, the first lower insulation layer 110a may be patterned to form first openings exposing the lower pads 130.

The first lower insulation layer 110a may include, e.g., a polymer, a dielectric layer, or the like. For example, the first lower insulation layer 110a may include a photosensitive insulation layer such as a photo-imageable dielectric (PID).

In one or more example embodiments, the first lower insulation layer 110a may be formed by a vapor deposition process or a spin coating process. In one or more example embodiments, the lower pads 130 may be formed by an electroplating process, an electro-less plating process, a vapor deposition process, or the like.

Lower redistribution patterns 120 may be formed on the first lower insulation layer 110a and inside the first openings, and may directly contact the lower pads 130 through the first openings. Particularly, a seed layer may be formed on a portion of the first lower insulation layer 110a and surfaces of the first openings. The seed layer may be patterned, and an electroplating process may be performed on the seed layer to form the lower redistribution patterns 120. For example, the lower redistribution pattern 120 may include aluminum (Al), copper (Cu), tin (Sn), nickel (Ni), gold (Au), platinum (Pt), or an alloy thereof.

Subsequently, a second lower insulation layer 110b may be formed on the first lower insulation layer 110a to cover the lower redistribution patterns 120, and then the second lower insulation layer 110b may be patterned to form second openings exposing the lower redistribution pattern 120. First bonding pads 140 and second bonding pads 150 may be formed on the second lower insulation layer 110b and inside the second openings, and may directly contact the lower redistribution patterns 120 through the second openings. The first bonding pads 140 may be positioned in an area where conductive post structures are to be formed. The second bonding pads 150 may be arranged to overlap an area where the first semiconductor chip is placed.

Subsequently, a third lower insulation layer 110c may be formed on the second lower insulation layer 110b to fill a space between the first and second bonding pads 140 and 150.

The first and second bonding pads 140 and 150 are formed by the same processes, and thus first and second bonding pads 140 and 150 may include the same metal.

Accordingly, the lower redistribution layer structure 100 including the first to third lower insulation layers 110a, 110b and 110c, the lower pad 130, the first and second bonding pads 140 and 150, and the lower redistribution pattern 120 may be formed on the carrier substrate C1.

The lower redistribution layer structure 100 may serve as a front redistribution layer (FRDL) of a fan-out package. The first and second bonding pads 140 and 150 may be exposed by an upper surface of the lower redistribution layer structure 100.

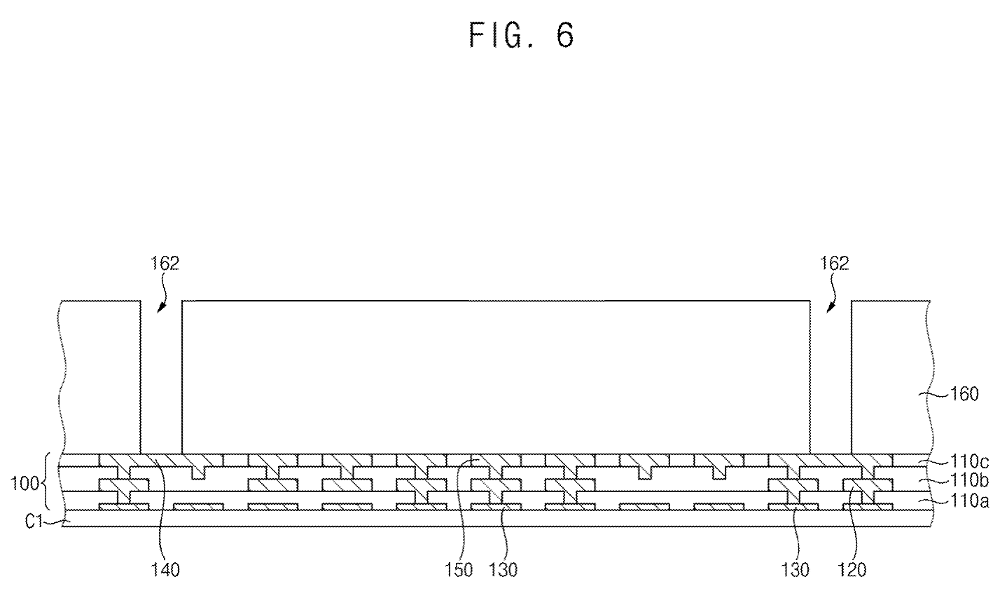

Referring to FIG. 6, a first photoresist layer may be formed on the upper surface of the lower redistribution layer structure 100. Thereafter, an exposure process and a development process may be performed on the first photoresist layer to form third openings 162. Accordingly, a first photoresist pattern 160 having the third openings 162 may be formed on the lower redistribution layer structure 100. Each of the third openings 162 may expose at least a portion of the first bonding pad 140.

Each of the third openings 162 may be positioned at an area for forming a conductive post structure, and the first photoresist patterns 160 may serve as a mold for forming the conductive post structures.

An upper surface of the conductive post structure may be coplanar with or higher than an upper surface of a first semiconductor chip mounted on the lower redistribution layer structure 100 by subsequent processes. Therefore, an upper surface of the first photoresist pattern 160 may be higher than an upper surface of the first semiconductor chip mounted in the subsequent processes. A vertical height of the first photoresist pattern 160 may be higher than a vertical height of the first semiconductor chip.

In one or more example embodiments, a width of the third opening 162 may be same as a width of a first conductive post included in the conductive post structure.

In one or more example embodiments, a sidewall of the third opening 162 may have a substantially vertical slope. In one or more example embodiments, a lower width of the third opening 162 may be substantially the same as an upper width of the third opening 162.

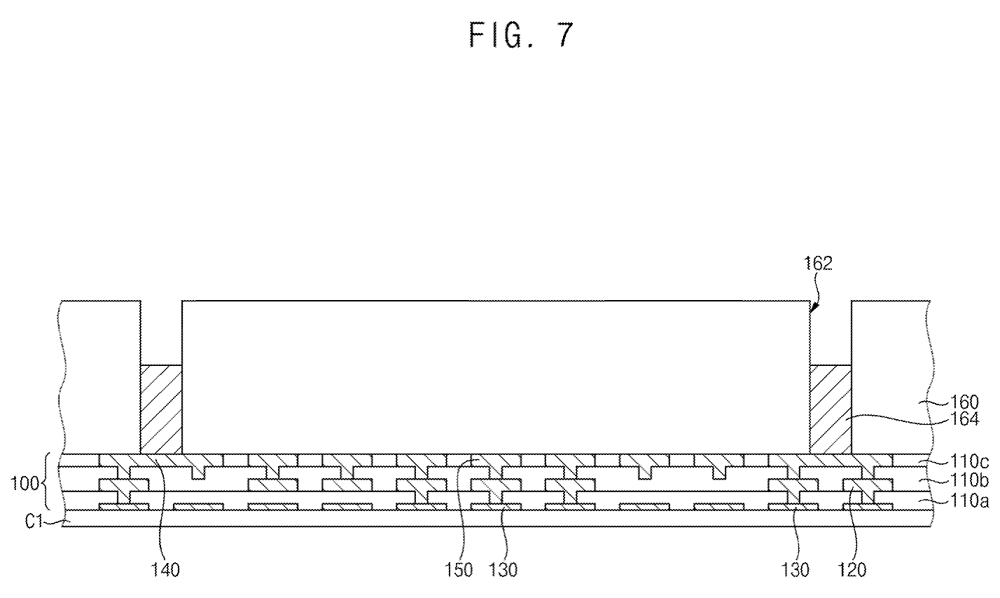

Referring to FIG. 7, a conductive material may partially fill the third openings 162 to form first preliminary conductive posts 164 on the first bonding pads 140.

In one or more example embodiments, the first preliminary conductive posts 164 may fill to have a vertical height in a range about 50% to about 80% of the vertical height of the first photoresist pattern 160.

In one or more example embodiments, the first preliminary conductive posts 164 may be formed by an electroplating process or an electro-less plating process. In one or more example embodiments, the first preliminary conductive posts 164 may include copper. Each of the first preliminary conductive posts 164 may contact an upper surface of the first bonding pad 140, and may extend from the upper surface of the first bonding pad 140 in the vertical direction. The first preliminary conductive posts 164 may be electrically connected to the lower redistribution pattern 120 included in the lower redistribution layer structure 100. The first preliminary conductive post 164 may be arranged in a fan-out region corresponding to an outer area of the first semiconductor chip 100.

While two first preliminary conductive posts 164 in the fan-out region are illustrated, this is provided as an example. Therefore, it will be understood that the disclosure is not limited thereto.

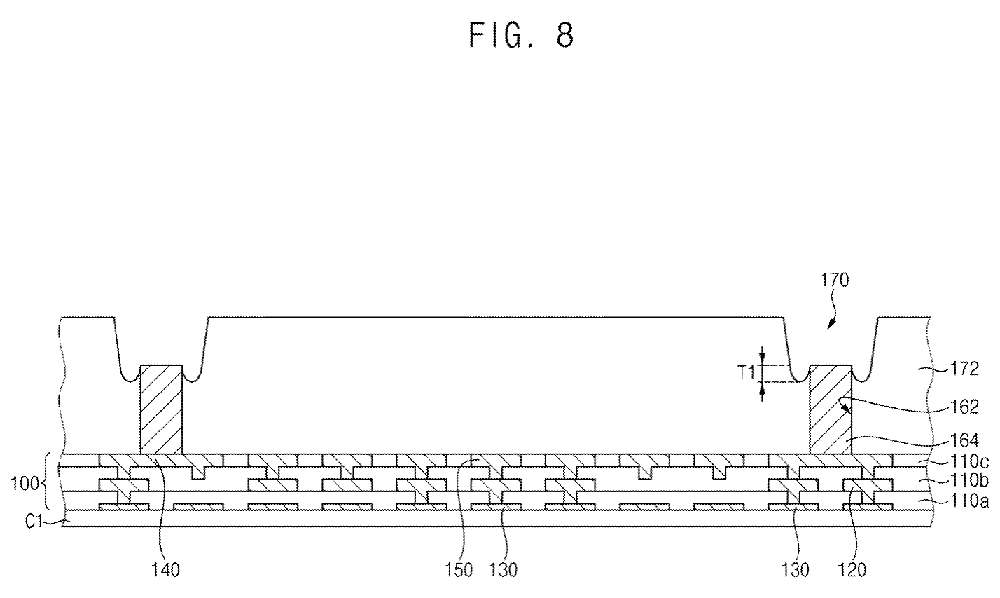

Referring to FIG. 8, in a state where first preliminary conductive posts 164 are formed, an exposed surface of the first photoresist pattern 160 may be partially removed to form a second photoresist pattern 172 having a fourth opening 170 on each of the first preliminary conductive posts 164.

The fourth opening 170 may have a sidewall slope such that a width of the fourth opening 170 may gradually decrease from the top to the bottom thereof. For example, in a cross-sectional view, the fourth opening 170 may have an inverted trapezoidal shape.

An upper width of the fourth opening 170 may be greater than a lower width of the fourth opening 170. Further, the lower width of the fourth opening 170 may be greater than a width of the third opening 162 beneath the fourth opening 170.

A lowermost portion of the fourth opening 170 may be lower than an uppermost surface of the first preliminary conductive post 164. In one or more example embodiments, in a cross-sectional view, a first portion T1 of the fourth opening 170 positioned lower than the uppermost surface of the first preliminary conductive post 164 may have a downwardly rounded shape. In one or more example embodiments, the first portion T1 of the fourth opening 170 may be spaced apart from at least a portion of an upper sidewall of the first preliminary conductive post 164, and may have a trench shape having a fine width and surrounding the upper sidewall of the first preliminary conductive post 164. A portion of the second photoresist pattern 172 may be interposed between the first portion T1 of the fourth opening 170 and the upper sidewall of the first preliminary conductive post 164.

For forming the second photoresist pattern 172, a descum process may be performed to partially remove the exposed surface of the first photoresist pattern 160 in the state where the first preliminary conductive posts 164 are formed. The descum process may include, e.g., a plasma ashing process using oxygen gas.

When the descum process is performed, an exposed third opening 162 of the first photoresist pattern 160 may be etched laterally and downwardly. For example, an upper portion of the exposed third opening 162 may be etched more than a lower portion of the exposed third opening 162. Accordingly, in a cross-sectional view, the fourth opening 170 may have an inverted trapezoidal shape. In addition, as a portion of the third opening 162 adjacent to the upper surface of the first preliminary conductive post 164 is etched, the first photoresist pattern 160 adjacent to the upper surface of the first preliminary conductive post 164 may also be removed downward. Accordingly, the first portion T1 of the fourth opening 170 having a trench shape may be formed to surround an upper portion of the first preliminary conductive post 164. Meanwhile, in the descum process, the upper surface of the first photoresist pattern 160 may also be partially etched. Therefore, a thickness of the first photoresist pattern 160 may slightly decrease in the descum process.

In one or more example embodiments, a wet cleaning process of the second photoresist pattern 172 may be further performed after performing the descum process.

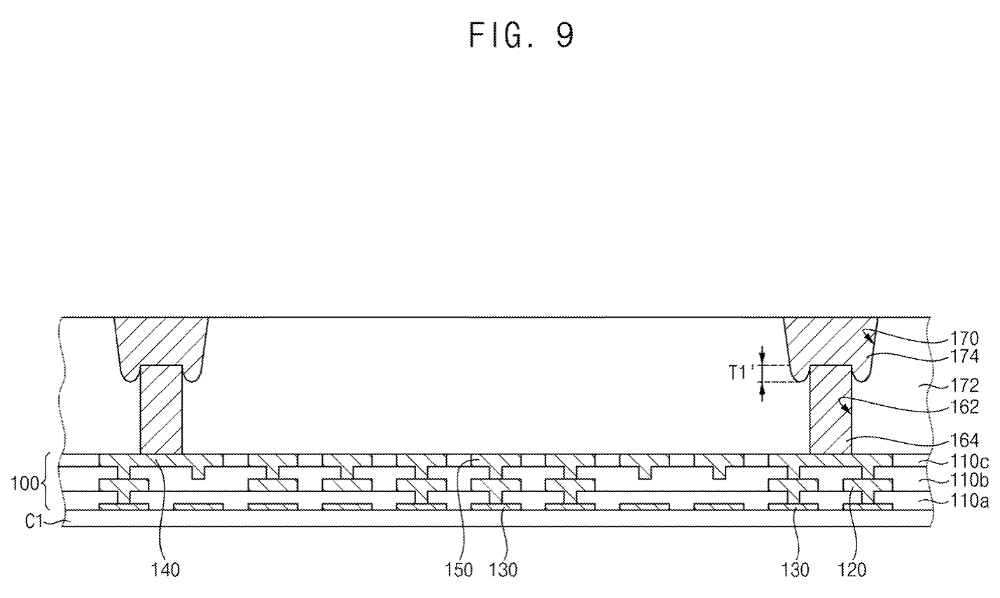

Referring to FIG. 9, a conductive material may be formed to fill the fourth openings 170 to form a second preliminary conductive post 174 on each of the first preliminary conductive posts 164. The first and second preliminary conductive posts 164 and 174 may include the same material.

In one or more example embodiments, the second preliminary conductive post 174 may be formed by an electroplating process or an electro-less plating process. In one or more example embodiments, the second preliminary conductive post 174 may include copper.

Since the second preliminary conductive post 174 is formed in the fourth opening 170, the second preliminary conductive post 174 may a shape the same as a shape of the fourth opening 170. The second preliminary conductive post 174 may have a sidewall slope such that a width of second preliminary conductive post 174 may gradually decrease from the top to the bottom thereof. A first portion T1' of the second preliminary conductive post 174, which is positioned lower than the uppermost surface of the first preliminary conductive post 164, may be spaced apart from at least a portion of the sidewall of the first preliminary conductive post 164, and may surround the upper sidewall of the first preliminary conductive post 164. The first portion T1' of the second preliminary conductive post 174 may be positioned inside of the trench of the first portion T of the fourth opening 170.

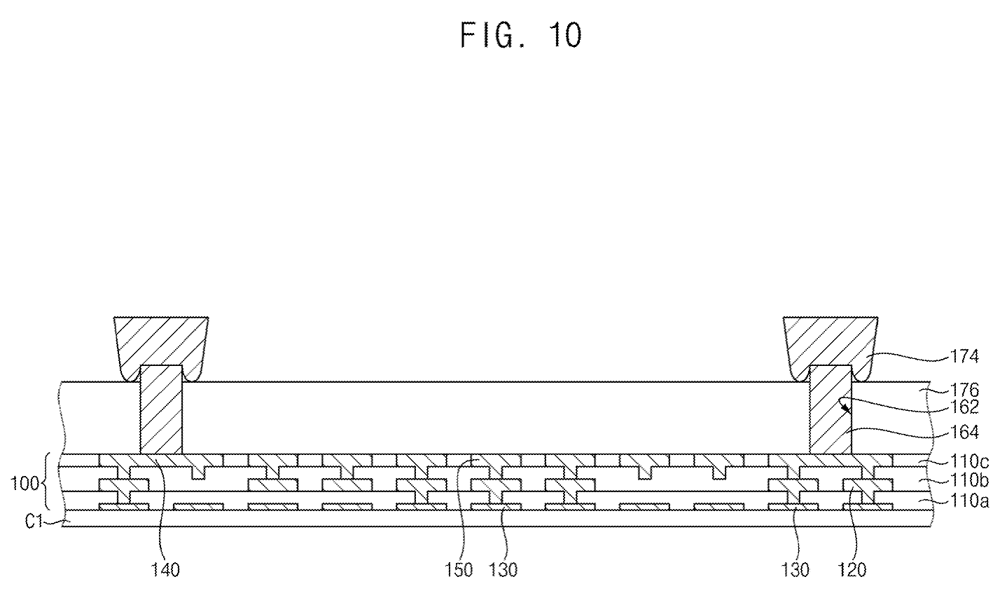

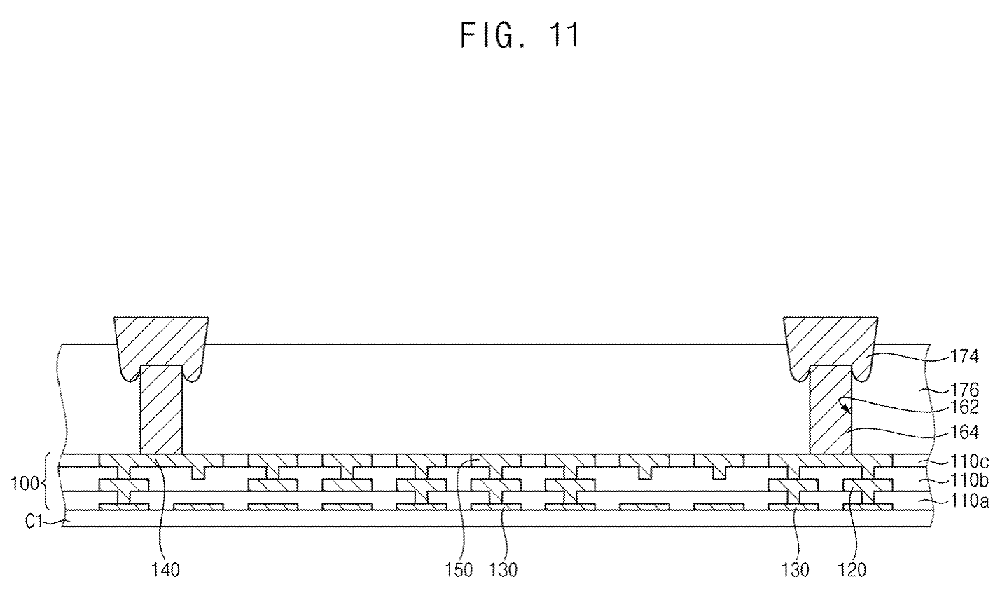

Referring to FIGS. 10 or 11, the second photoresist pattern 172 may be partially removed to expose at least a portion of the second preliminary conductive post 174 to form a third photoresist pattern 176. The partial removing process of a portion of the third photoresist pattern 176 may include a plasma ashing process.

In one or more example embodiments, as shown in FIG. 10, the third photoresist pattern 176 may expose an entirety of the second preliminary conductive post 174, and may not expose the first preliminary conductive post 164 beneath a lowermost portion of the second preliminary conductive post 174.

In one or more example embodiments, as shown in FIG. 11, the third photoresist pattern 176a may expose only an upper portion of the second preliminary conductive post 174, and may not expose a lower portion of the second preliminary conductive post 174 and the first preliminary conductive post 164.

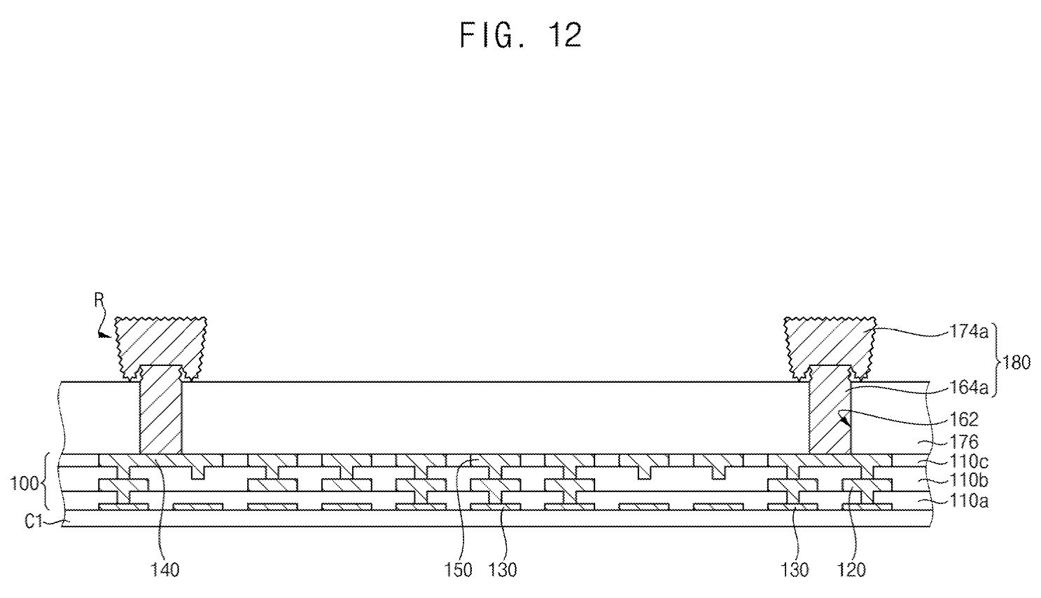

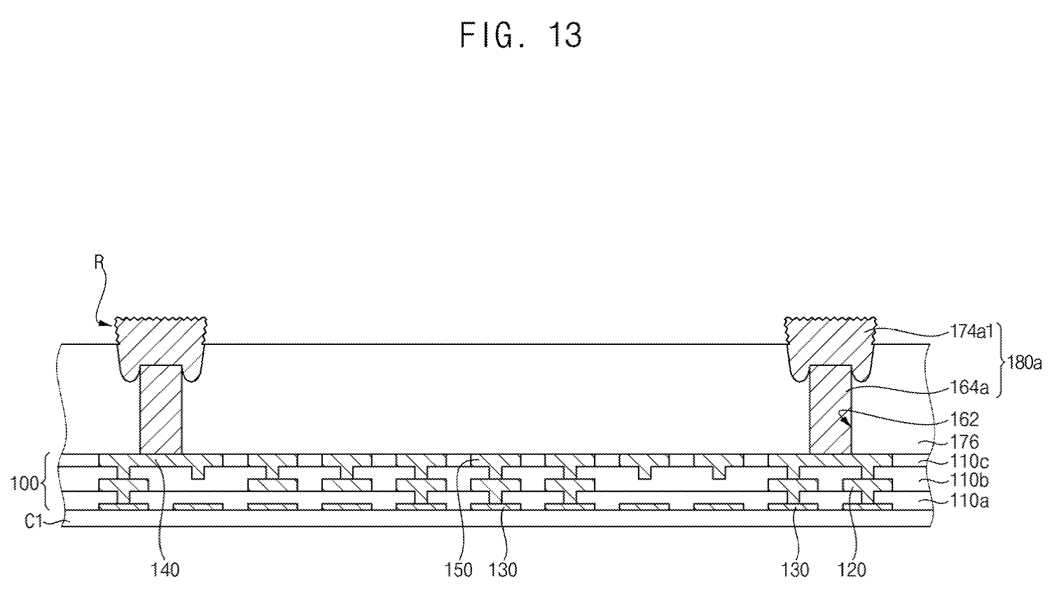

Referring to FIGS. 12 or 13, the surfaces of the second preliminary conductive posts 174 exposed by the third photoresist pattern 176 may be etched at a very low etch rate to form conductive post structures 180 in which a first conductive post 164a and a second conductive post 174a are stacked. The etching process may include, e.g., a wet etching process using an etchant containing an organic acid.

After the etching process, a surface of the conductive post structure 180 from the top to a predetermined height downward may have a relatively high surface roughness and may have an unevenness R. For example, an exposed surface of the second preliminary conductive post 174 may have the unevenness R, after the etching process.

Depending on a shape of the third photoresist pattern 176, an uneven portion of the conductive post structure 180 where the unevenness R is formed may vary.

In one or more example embodiments, as shown in FIG. 10, when the third photoresist pattern 176 exposes the entire surface of the second preliminary conductive post 174, as shown in FIG. 12, the unevenness R may be formed on the entire surface of the second conductive post 174a and an upper sidewall of the first conductive post 164a facing the first portion T1' of the second preliminary conductive post 174. In this case, the conductive post structure 180 as shown in FIG. 3 may be formed by subsequent processes.

In one or more example embodiments, as shown in FIG. 11, when the third photoresist pattern 176 exposes only a portion of the upper portion of the second preliminary conductive post 174, as shown in FIG. 13, the unevenness R may be formed only on an upper surface of the second conductive post 174a1. In this case, the conductive post structure 180a as shown in FIG. 4 may be formed by subsequent processes.

The uneven portion (e.g., the upper sidewall) of the conductive post structure 180 may have a first arithmetic mean roughness. In one or more example embodiments, the first arithmetic mean roughness may be in a range of about 10nm to about 2000nm. For example, the surface of the second conductive posts 174a may have the first arithmetic mean roughness.

Hereinafter, subsequent processes are described with reference to the structure shown in FIG. 12. However, the same or similar subsequent processes may also be performed on the structure shown in FIG. 13 to form a semiconductor package.

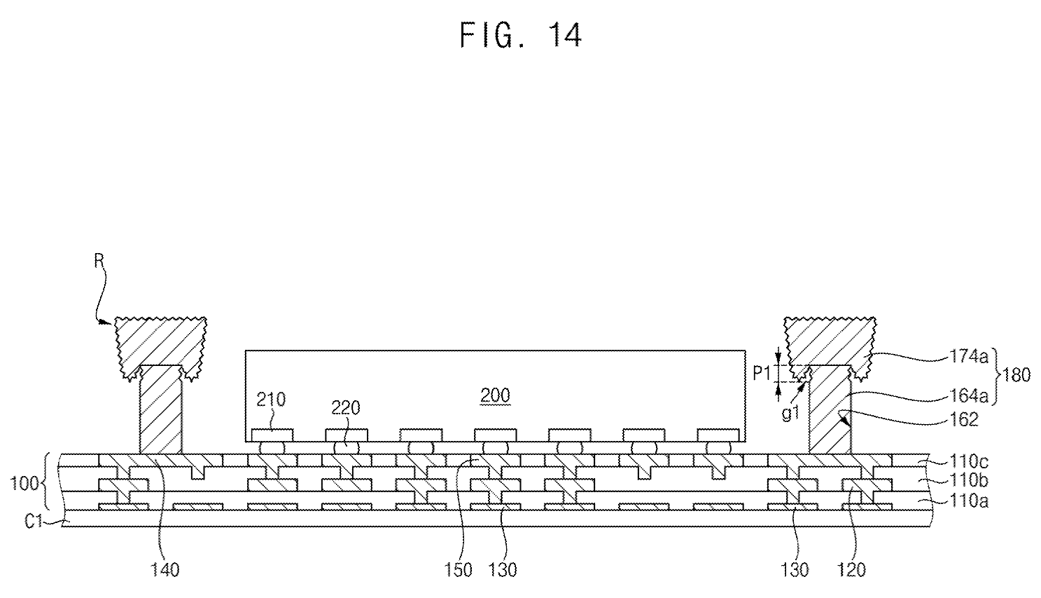

Referring to FIG. 14, the third photoresist pattern 176 may be removed by an ashing and stripping process. Therefore, the sidewalls and the upper surface of the conductive post structure 180 may be exposed.

A first semiconductor chip 200 may be mounted within a fan-in region of the lower redistribution layer structure 100.

The first semiconductor chip 200 may be placed such that a front surface (i.e., an active surface), where chip pads 210 are formed, may face the lower redistribution layer structure 100. The chip pads 210 of the first semiconductor chip 200 may be electrically connected to the first bonding pads 140 of the lower redistribution layer structure 100 via conductive bumps 220. Accordingly, the first semiconductor chip 200 may be electrically connected to the lower redistribution patterns 120 of the lower redistribution layer structure 100 via conductive bumps 220. For example, the conductive bumps 220 may include microbumps (uBumps).

In one or more example embodiments, the first semiconductor chip 200 may be a logic chip including logic circuits. The logic chip may be a controller that controls memory chips. In one or more example embodiments, the first semiconductor chip 200 may be a processor chip such as an ASIC serving as a host, such as a CPU, GPU, or SOC, or an AP (Application Processor).

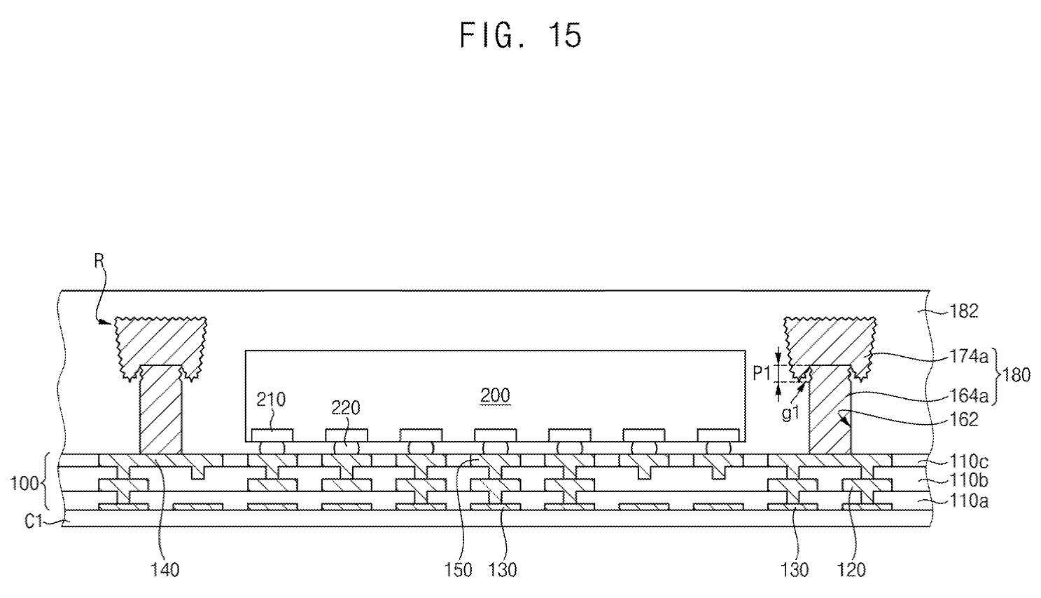

Referring to FIG. 15, a sealant 182 may be formed on the lower redistribution layer structure 100 to cover the first semiconductor chip 200 and the conductive post structures 180. The sealant 182 may be formed to fill a space between the lower redistribution layer structure 100 and the first semiconductor chip 200 and to least partially cover the upper surface of the first semiconductor chip 200 and the conductive post structures 180. For example, the sealant 182 may be or include an encapsulant such as an epoxy mold compound (EMC). The sealant 182 may include, e.g., ultraviolet (UV) resin, polyurethane resin, silicone resin, silica filler, etc.

The sealant 182 may be formed by a molding process, a screen printing process, a lamination process, etc.

The second conductive post 174a may have a sidewall slope such that a width of the second conductive post 174a may gradually decrease from an uppermost portion to the lower portion thereof. The width of the second conductive post 174a may be greater than the width of the first conductive post 164a. Accordingly, an amount (or volume) of the sealant 182 on the lower sidewall of the second conductive post 174a may be greater than an amount (or volume) of the sealant 182 on the upper sidewall of the second conductive post 174a.

A first portion P1 of the second conductive post 174a positioned lower than the uppermost surface of the first conductive post 164a may be spaced apart from at least a portion of the upper sidewall of the first conductive post 164a, and may surround the upper sidewall of the first conductive post 164a. In a portion adjacent to an interface between the first conductive post 164a and the second conductive post 174a, the upper portion of the first conductive post 164a and a lower portion (e.g., the first portion) of the second conductive post 174a may face each other, and a gap g1 may be formed between facing portions of the first and second conductive posts 164a and 174a. Accordingly, the sealant 182 may fill the gap g1 between the facing portions of the first and second conductive posts 164a and 174a. The sealant 182 filling the gap gl may surround an edge of a bottom surface of the second conductive post 174a. Since the first portion P1 of the second conductive post 174a may be embedded within the sealant 182, a lower portion of the second conductive post 174a may be strongly supported by the sealant 182.

The sealant 182 may directly contact sidewalls of the conductive post structures 180. In general, an adhesive property of an interface between the conductive post structure and the sealant are not good, and in particular, the adhesive property between an upper sidewall of the conductive post structure and the sealant may not be good. However, since the sidewall of the conductive post structure 180 extending downward from the top to the predetermined height have the unevenness R, the adhesive property between the upper sidewall of the conductive post structure 180 and the sealant 182 may be improved.

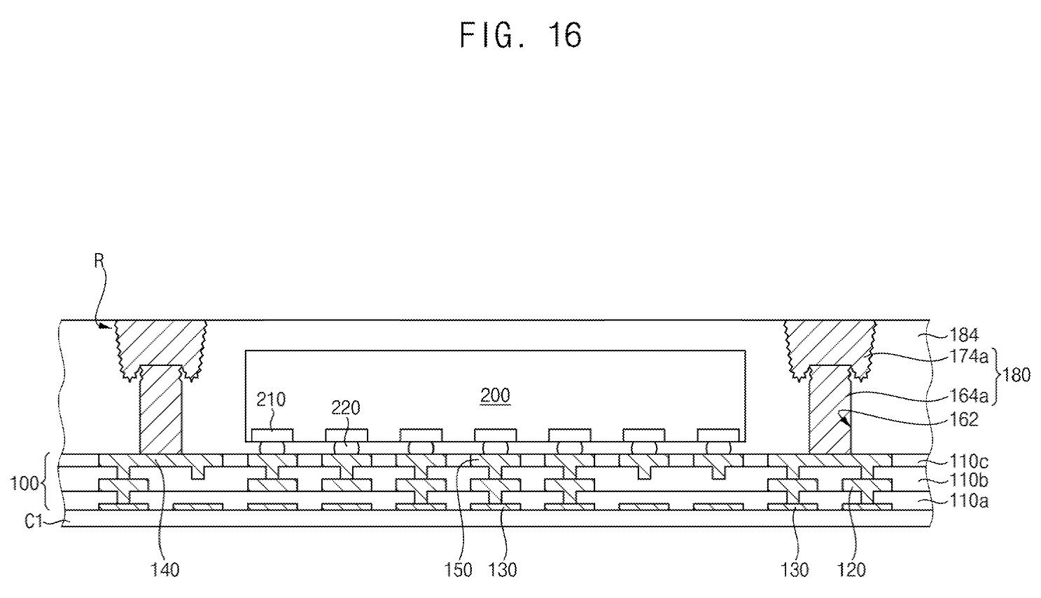

Referring to FIG. 16, an upper portion of the sealant 182 may be removed by a planarization process to expose the upper surfaces of the conductive post structures 180. Accordingly, the sealant 182 may be formed into a first sealing member 184 by the planarization process. In one or more example embodiments, the first sealing member 184 may cover a lower portion, sidewalls, and an upper surface of the first semiconductor chip 200.

The planarization process of the sealant 182 may include a grinding process. In the grinding process, the upper surfaces of the conductive post structures 180 may also be planarized.

Since the sealant 182 is grinded under a pressure in the planarization process, the pressure and a mechanical stress may also be applied to the upper portions of the conductive post structures 180. The pressure and mechanical stress applied to the upper portions of the conductive post structures 180 may cause defects, such as cracks, in the conductive post structures 180 may occur.

However, as described above, the lower portion of the second conductive post 174a included in the conductive post structures 180 may be strongly supported by the sealant 182. Accordingly, the conductive post structure 180 may have a high endurance with respect to the pressure and the mechanical stress applied to the upper portions of the conductive post structures 180. Therefore, the defect, such as the crack, in the conductive post structures 180 may be avoided or reduced.

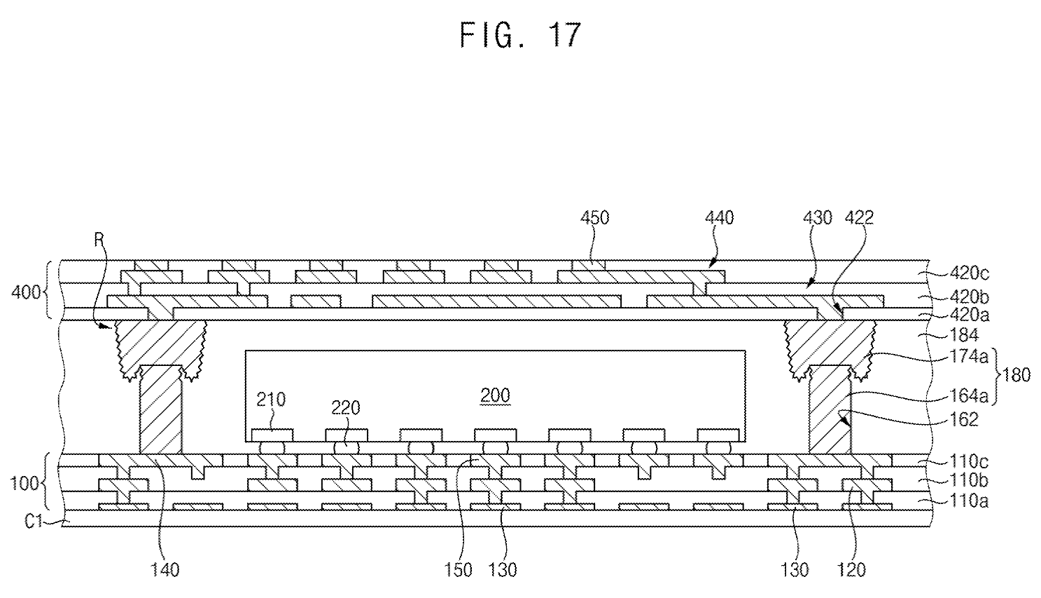

Referring to FIG. 17, an upper redistribution layer structure 400 may be formed on the upper surfaces of the first sealing member 184 and the conductive post structures 180. The upper redistribution layer structure 400 may include upper redistribution patterns 430 and 440, upper insulation layers 420a, 420b and 420c, and a third bonding pad 450.

The upper insulation layers 420a, 420b and 420c may include, e.g., a polymer, a dielectric layer, or the like. For example, the upper insulation layers 420a, 420b and 420c may include a photosensitive insulation layer such as a photoimageable dielectric (PID). The upper insulation layers 420a, 420b and 420c may be formed by a vapor deposition process, a spin coating process, or the like.

A first upper insulation layer 420a may be formed on the upper surface of the first sealing member 184 and the upper surfaces of the conductive post structures 180. The first upper insulation layer 420a may be patterned by a photolithography process to form fifth openings 422 that expose the upper surfaces of the conductive post structures 180, respectively. At least a portion of the upper surface of each of the conductive post structures 180 may be exposed by bottom of the fifth opening 422.

A seed layer may be formed on the surfaces of the conductive post structures 180 exposed by the fifth openings 422 and surfaces of the fifth openings 422. The seed layer may be patterned, and an electroplating process may be performed on the seed layer to form a first upper redistribution pattern 430 including metal. The first upper redistribution pattern 430 may include a first via contact contacting the upper surface of the conductive post structure 180 and a first upper wiring on the first via contact.

After forming a second upper insulation layer 420b on the first upper insulation layer 420a and the first upper redistribution pattern 430, the second upper insulation layer 420b may be patterned to form sixth openings exposing at least portions of the first upper redistribution pattern 430. Thereafter, a second upper redistribution pattern 440 may be formed on the second upper insulation layer 420b to fill each of the sixth openings. The second upper redistribution pattern 440 may include a second via contact contacting the first upper redistribution pattern 430 and a second upper wiring on the second via contact.

Third bonding pads 450 may be formed on the second upper redistribution pattern 440. The third bonding pads 450 may be arranged in an area corresponding to an area where an upper package is to be placed. Thereafter, a third upper insulation layer 420c may be formed on the second upper redistribution pattern 440 to fill a space between the third bonding pads 450.

The upper redistribution layer structure 400 may be a backside redistribution layer (BRDL) of the fan-out package. Upper surface of the third bonding pads 450 may be exposed through the third upper insulation layer 420c, which is an uppermost upper insulation layer.

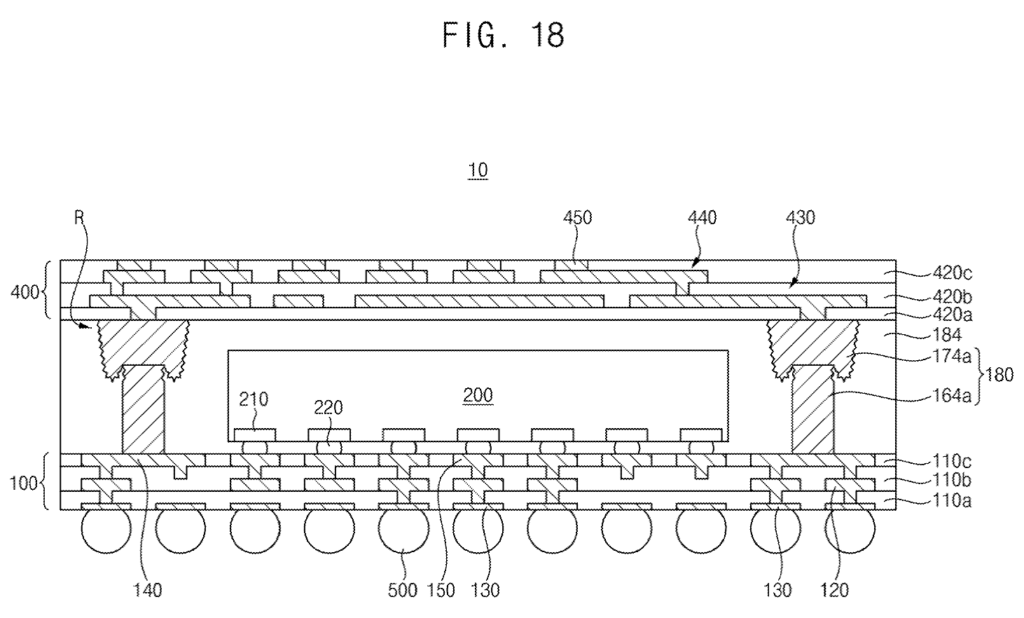

Referring to FIG. 18, the carrier substrate C1 may be removed so that a lower surface of the lower redistribution layer structure 100 may be exposed to an outside.

External connection members 500 for electrically connecting the lower redistribution patterns 120 may be formed on the lower pads 130 of the lower redistribution layer structure 100. The external connection members 500 may include, e.g., solder balls, conductive bumps, etc.

The structures on the lower redistribution layer structure 100 may be cut by a sawing process to form an individualized semiconductor package 10. The semiconductor package 10 may include the first sealing member 184, the lower redistribution layer structure 100 formed on a lower surface of the first sealing member 184, the first semiconductor chip 200 formed within the first sealing member 184, and the upper redistribution layer structure 400 formed on the upper surface of the first sealing member 184.

In the semiconductor package 10, delamination and cracks caused by the conductive post structures 180 may be reduced. Therefore, the semiconductor package 10 may have high reliability.

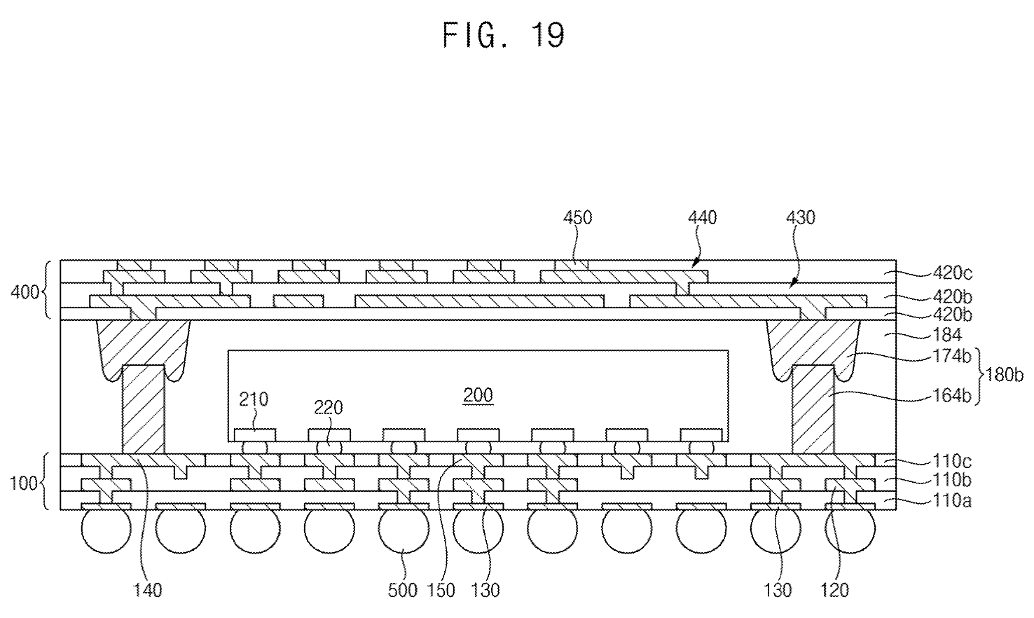

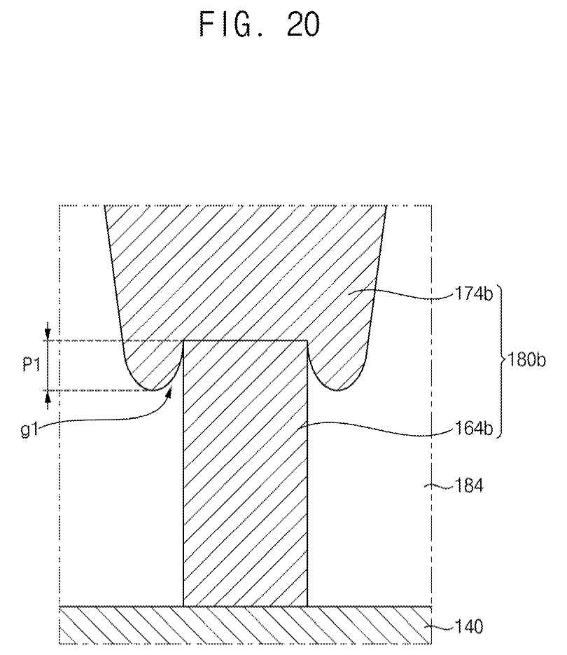

FIG. 19 is a cross-sectional view illustrating a semiconductor package according to one or more example embodiments. FIG. 20 is an enlarged cross-sectional view of a conductive post structure of a semiconductor package according to one or more example embodiments.

The semiconductor package shown in FIGS. 19 and 20 is the same or similar to the semiconductor package shown in FIG. 1, except for a surface of the conductive post structure. Therefore, a repeated description thereof will be omitted.

Referring to FIGS. 19 and 20, the conductive post structure 180b may include a first conductive post 164b and a second conductive post 174b.

The first conductive post 164b may be similar to the first conductive post 164a described with reference to FIGS. 1 and 3. However, a sidewall of the first conductive post 164b may not have unevenness. The sidewall of the first conductive post 164b may have a substantially smooth surface.

The second conductive post 174b may be similar to the second conductive post 174a described with reference to FIGS. 1 and 3. However, a sidewall of the second conductive post 174b may not have unevenness. The sidewall of the second conductive post 174b may have a substantially smooth surface.

The process for forming the conductive post structure 180b may be the same as or similar to the processes described with reference to FIGS. 5 to 18. However, the etching process for forming the unevenness on the sidewall of the conductive post structure 180a may be omitted. Therefore, after performing the processes described with reference to FIGS. 5 to 9, the processes described with reference to FIGS. 14 to 18 may be performed immediately. The processes described with reference to FIGS. 10 to 13 may not be performed.

Occurrence of a crack in conductive post structure 180b due to the pressure and the stress applied to the upper surface of the conductive post structure 180b may decrease. Accordingly, delamination caused by a crack in the conductive post structure 180b may be reduced.

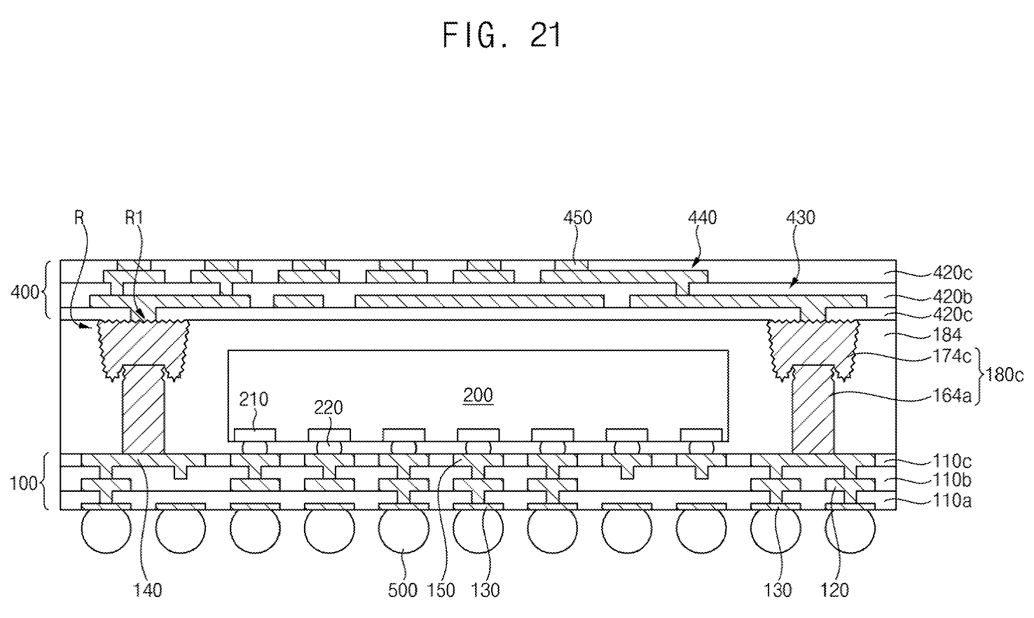

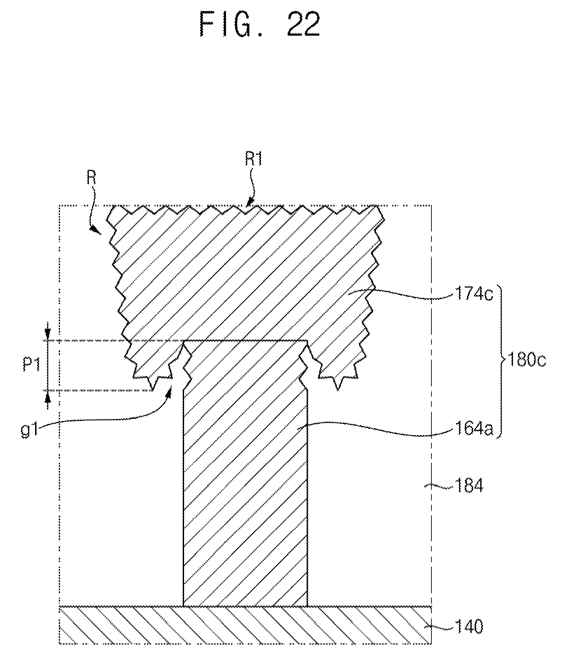

FIG. 21 is a cross-sectional view illustrating a semiconductor package according to one or more example embodiments. FIG. 22 is an enlarged cross-sectional view of a conductive post structure of a semiconductor package according to one or more example embodiments.

The semiconductor package shown in FIGS. 21 and 22 may be the same as or similar to the semiconductor package shown in FIG. 1, except for a surface of a conductive post structure. Therefore, a repeated description will be omitted.

Referring to FIGS. 21 and 22, the conductive post structure 180c may include a first conductive post 164a and a second conductive post 174c.

The first conductive post 164a may be substantially the same as the first conductive post 164a described with reference to FIGS. 1 and 3.

The second conductive post 174c may be similar to the second conductive post 174a described with reference to FIGS. 1 and 3. However, the sidewall of the second conductive post 174c may have the unevenness R, and in addition, the upper surface of the second conductive post 174c may have an unevenness R1. By the unevenness R1 on the upper surface of the second conductive post 174c, the adhesive property between the first upper insulation layer 420a on the upper surface of the second conductive post 174c may be improved.

The process for forming the conductive post structure 180c may be the same as or similar to the processes described with reference to FIGS. 5 to 18. However, processes for forming the unevenness on the upper surface of the conductive post structure 180c may be further performed. That is, after performing the process described with reference to FIGS. 5 to 16, an etching process for forming the unevenness on the upper surface of the conductive post structure 180c may be further performed. Thereafter, the processes described with reference to FIGS. 17 and 18 may be performed to form the conductive post structure 180c shown in FIGS. 21 and 22.

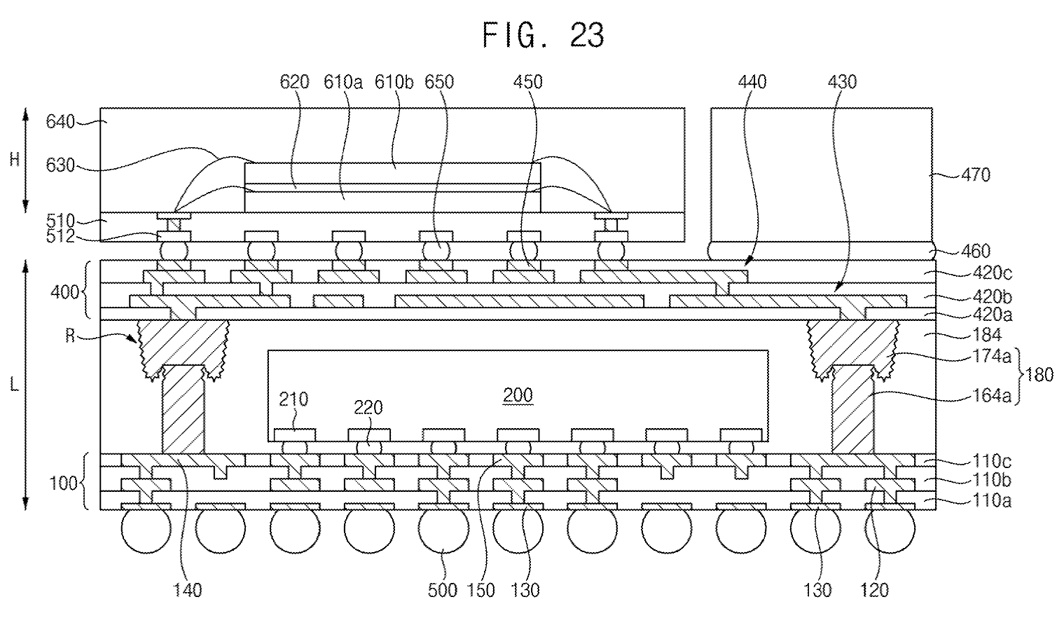

FIG. 23 is a cross-sectional view illustrating a semiconductor package according to one or more example embodiments.

The semiconductor package shown in FIG. 23 may have a structure in which an upper package and a heat dissipation structure are stacked on the semiconductor packages described above.

Referring to FIG. 23, the semiconductor package described with reference to FIGS. 1 to 3 may be provided as a lower package L. An upper package H may be stacked on the lower package L.

The upper package H may include a package substrate 510, at least one second semiconductor chip 610a and 610b mounted on the package substrate 510, and a second sealing member 640 on the second semiconductor chip 610a and 610b and the package substrate 510. Bonding wires 630 may be further included in the upper package H. The bonding wires 630 may connect the second semiconductor chips 610a and 610b and the package substrate 510.

In one or more example embodiments, in the upper package H, a plurality of second semiconductor chips 610a and 610b may be sequentially stacked on the package substrate 510 by an adhesive member 620. The bonding wires 630 may connect the upper chip pads of the second semiconductor chips 610a and 610b and fourth bonding pads 512 on the upper portion of the package substrate 510.

As shown in FIG. 23, the upper package H includes two second semiconductor chips 610a and 610b mounted by a wire bonding process. However, the number of semiconductor chips in the upper package H, a mounting process, etc., are not limited thereto.

A conductive connection member 650 may be disposed on the third bonding pad 450 of the lower package L, and the upper package H may be bonded on conductive connection members 650. The conductive connection members 650 may include, e.g., solder balls, conductive bumps, etc. Each of the conductive connection member 650 may be disposed between the third bonding pad 450 on the upper redistribution layer structure 400 and a fourth bonding pad 512 of the package substrate 510. Accordingly, the lower package L and the upper package H may be electrically connected to each other by the conductive connection members 650.

The heat dissipation structure 470 may be stacked on the lower package L. The heat dissipation structure 470 may be referred to as a heat path block (HPB). A thermal interface material 460 may be interposed between the lower package L and the heat dissipation structure 470, so that the heat dissipation structure 470 may be bonded on the lower package L. The heat dissipation structure 470 may be spaced apart from the lower package L by the thermal interface material 460. Furthermore, the heat dissipation structure 470 may be spaced apart from the upper package H.

In one or more example embodiments, the heat dissipation structure 470 may extend in a first direction along one edge of the lower package L.

In one or more example embodiments, the heat dissipation structure 470 may extend in the first direction and a second direction along two edges of the lower package L, respectively. For example, the heat dissipation structure 470 may have an L-shape.

In one or more example embodiments, the heat dissipation structure 470 may have a rectangular ring shape surrounding the lower package L.

The heat dissipation structure 470 may be provided to dissipate heat generated while operating the first semiconductor chip 200 included in the lower package L. The heat dissipation structure 470 may include a metal having high thermal conductivity (e.g., copper). An arrangement of the heat dissipation structure 470 is not limited thereto, and the heat dissipation structure 470 may be disposed in a remaining space after the second semiconductor chips 610a and 610b are disposed on the lower package L.

In FIG. 23, the semiconductor package may have the upper package H stacked on the lower package L, and the lower package L is illustrated as the semiconductor package shown in FIG. 1. However, the disclosure is not limited thereto. The lower package may be selected from among the semiconductor packages according to the embodiments described above.

According to one or more embodiments, there is provided a method of manufacturing a semiconductor package. The method may include: forming a lower redistribution layer structure including a lower redistribution pattern; forming a conductive post structure on the lower redistribution layer structure such that the conductive post structure is electrically connected to the lower redistribution layer structure; mounting a semiconductor chip on the lower redistribution layer structure such that the first semiconductor chip is electrically connected to the lower redistribution pattern; forming a sealing member on the lower redistribution layer structure such that the sealing member contacts surrounds the conductive post structure and the semiconductor chip; and forming an upper redistribution layer structure on an upper surface of the sealing member and an upper surface of the conductive post structure. Here, the conductive post structure may be formed such that a first conductive post extends from an upper surface of the lower redistribution layer structure in a vertical direction, wherein a sidewall of the first conductive post has a vertical slope, and a second conductive post is formed on an upper surface of the first conductive post such that a width of the second conductive post gradually decreases from a top to a bottom thereof and the second conductive post has a first portion positioned lower than an uppermost surface of the first conductive post.

According to one or more embodiments, there is provided a method of manufacturing a semiconductor package. The method may include: forming a lower redistribution layer structure including a lower insulation layer, a lower redistribution pattern and a bonding pad; mounting a semiconductor chip on the lower redistribution layer structure such that the semiconductor chip is electrically connected to the lower redistribution pattern; forming a conductive post structure to be spaced apart from the semiconductor chip such that the conductive post structure contacts the bonding pad and an upper sidewall of the conductive post structure includes an uneven portion having unevenness; forming a sealing member on the lower redistribution layer structure and the semiconductor chip such that the sealing member surrounds the conductive post structure and the semiconductor chip; and forming an upper redistribution layer structure on an upper surface of the sealing member and an upper surface the conductive post structure. Here, the upper redistribution layer structure may be formed such that an upper insulation layer and an upper redistribution pattern are electrically connected to the conductive post structure.

According to one or more embodiments, there is provided a method of manufacturing a semiconductor package. The method may include: forming a lower redistribution layer structure including a lower redistribution pattern; forming a conductive post structure including a first conductive post and a second conductive post on the lower redistribution layer structure such that the first conductive post extends from an upper surface of the lower redistribution layer structure in a vertical direction, an upper width and a lower width of the first conductive post are equal, and the second conductive post is formed on an upper surface of the first conductive post with a width of the second conductive post gradually decreasing from a top to a bottom thereof; and forming an upper redistribution layer structure spaced apart from and facing the lower redistribution layer structure, the upper redistribution layer structure including an upper redistribution pattern connected to the lower redistribution pattern through the conductive post structure.

The foregoing is illustrative of various one or more example embodiments and is not to be construed as limiting thereof. Although a few one or more example embodiments have been described, those skilled in the art will readily appreciate that many modifications are possible in the one or more example embodiments without materially departing from the novel teachings and advantages of the disclosure.

What is claimed is:

1. A semiconductor package comprising:
a lower redistribution layer structure comprising a lower redistribution pattern;
a semiconductor chip on the lower redistribution layer structure, the semiconductor chip electrically connected to the lower redistribution pattern;
a conductive post structure on the lower redistribution layer structure, the conductive post structure electrically connected to the lower redistribution layer structure;
a sealing member on the lower redistribution layer structure, the sealing member contacting a sidewall of the conductive post structure and covering the semiconductor chip;
and an upper redistribution layer structure on an upper surface of the sealing member and an upper surface of the conductive post structure,wherein the conductive post structure comprises:a first conductive post extending from an upper surface of the lower redistribution layer structure in a vertical direction, wherein a sidewall of the first conductive post has a vertical slope; anda second conductive post on an upper surface of the first conductive post, wherein a width of the second conductive post decreases from a top to a bottom thereof, and the second conductive post has a portion positioned lower than an uppermost surface of the first conductive post.

2. The semiconductor package of claim 1, wherein a lower width of the second conductive post is greater than a width of the first conductive post.

3. The semiconductor package of claim 1, wherein the portion of the second conductive post surrounds an upper sidewall of the first conductive post while being spaced apart from at least a portion of the upper sidewall of the first conductive post.

4. The semiconductor package of claim 1, wherein the portion of the second conductive post has a downwardly rounded shape, in a cross-sectional view.

5. The semiconductor package of claim 1, wherein a gap is positioned between an upper sidewall of the first conductive post and the portion of the second conductive post, and
wherein the sealing member is in the gap.

6. The semiconductor package of claim 1, wherein the first conductive post has a height greater than or equal to 50% and less than or equal to 80% of a height of the conductive post structure.

7. The semiconductor package of claim 1, wherein a surface of the conductive post structure downward from an uppermost edge of the conductive post structure comprises an uneven portion having unevenness.

8. The semiconductor package of claim 7, wherein an arithmetic mean roughness of the surface of the uneven portion is in a range of 10 nm to 2000 nm.

9. The semiconductor package of claim 7, wherein a sidewall of the conductive post structure below the uneven portion does not have unevenness.

10. The semiconductor package of claim 1, wherein at least a portion of a surface of a sidewall of the second conductive post comprises an uneven portion having unevenness, and at least a portion of the surface of the sidewall of the first conductive post does not have unevenness.

11. The semiconductor package of claim 1, wherein the first conductive post and second conductive post comprise copper.

12. The semiconductor package of claim 1, wherein the sealing member comprises an epoxy mold compound (EMC).

13. A semiconductor package comprising:
a lower redistribution layer structure comprising a lower insulation layer, a lower redistribution pattern and a bonding pad;
a semiconductor chip on the lower redistribution layer structure, the semiconductor chip electrically connected to the lower redistribution pattern;
a sealing member on the lower redistribution layer structure and the semiconductor
chip;a conductive post structure passing through the sealing member and spaced apart from the semiconductor chip, wherein the conductive post structure contacts the bonding pad and an upper sidewall of the conductive post structure comprises an uneven portion having unevenness; and an upper redistribution layer structure on an upper surface the conductive post structure, the upper redistribution layer structure comprising an upper insulation layer and an upper redistribution pattern electrically connected to the conductive post structure.

14. The semiconductor package of claim 13, wherein an arithmetic mean roughness of the uneven portion is in a range of 10 nm to 2000 nm.

15. The semiconductor package of claim 13, wherein the conductive post structure comprises:
a first conductive post extending from an upper surface of the lower redistribution layer structure in a vertical direction, wherein a sidewall of the first conductive post has a vertical slope; and
a second conductive post on an upper surface of the first conductive post, wherein a width of the second conductive post decreases from a top to a bottom thereof, and the second conductive post has a portion positioned lower than an uppermost surface of the first conductive post.

16. The semiconductor package of claim 15, wherein the portion of the second conductive post surrounds an upper sidewall of the first conductive post while being spaced apart from at least a portion of the upper sidewall of the first conductive post.

17. The semiconductor package of claim 15, wherein the portion of the second conductive post has a downwardly rounded shape, in a cross-sectional view.

18. The semiconductor package of claim 15, wherein at least a portion of a surface of a sidewall of the second conductive post comprises an uneven portion having unevenness, and at least a portion of a surface of the sidewall of the first conductive post does not have unevenness.

19. A semiconductor package comprising:
a lower redistribution layer structure comprising a lower redistribution pattern;
an upper redistribution layer structure spaced apart from and facing the lower redistribution layer structure, and the upper redistribution layer structure comprising an upper redistribution pattern; and
a conductive post structure between the lower redistribution layer structure and the upper redistribution layer structure to connect the lower redistribution layer structure and the upper redistribution layer structure,
wherein the conductive post structure comprises:
a first conductive post extending from an upper surface of the lower redistribution layer structure in a vertical direction, wherein an upper width and a lower width of the first conductive post are equal; and
a second conductive post on an upper surface of the first conductive post, wherein a width of the second conductive post decreases from a top to a bottom thereof.

20. The semiconductor package of claim 19, wherein the second conductive post has a portion positioned lower than an uppermost surface of the first conductive post, and
wherein the portion of the second conductive post surrounds an upper sidewall of the first conductive post while being spaced apart from at least a portion of the upper sidewall of the first conductive post.
